(19) United States
(12) Patent Application Publication
(10) Pub. No.: US 2009/0226283 A1
(43) Pub. Date: Sep. 10, 2009

(54) Method For Separating Wafers From A Stack Of Wafers

(75) Inventors: Eivind Johannes Ovrelid, Trondheim (NO); Zuhair Kamil Sallom, Saupstad (NO); Thor Christian Tuv, Rasta (NO); Per Arne Wang, Porsgrunn (NO)

Correspondence Address: BIRCH STEWART KOLASCH & BIRCH, PO BOX 747, FALLS CHURCH, VA, 22040-0747, US

(73) Assignee: REC SCANWAFER AS, PORSGRUNN (NO)

(21) Appl. No.: 12/225,091

(22) PCT Filed: Mar. 13, 2007
(86) PCT No.: PCT/NO2007/000097

§ 371 Date: Jan. 9, 2009

(30) Foreign Application Priority Data
Mar. 13, 2006 (NO) 20061164

(51) Int. Cl. H01L 21/68; B65G 60/00; F26B 3/347; H05B 6/64

(52) U.S. Cl. 414/150; 414/804; 34/259; 219/679

(57) ABSTRACT

The invention concerns a method for individually separating wafers from a stack of wafers by placing the stack of wafers in a microwave chamber, and exposing the wafers for microwaves causing the water between the wafers to evaporate.

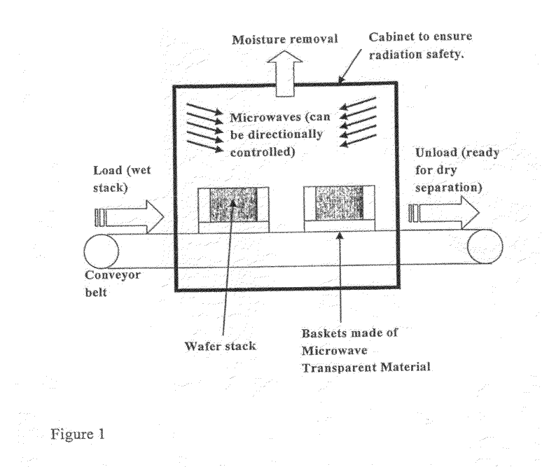

### TECHNICAL FIELD

The present invention concerns separation of stacked wafers. More specifically, the invention concerns a method for separating single wafers from a stack of wafers with minimal risk of breaking the wafers. A method using microwaves for this purpose is presented.

### BACKGROUND OF THE INVENTION

A wafer is a thin slice of semi conducting material used as the basis for developing microelectronics and photovoltaic devices. The semi conducting material is typically mono or multi-crystalline silicon, upon which microcircuits and photovoltaic devices are constructed by doping (for example, diffusion or ion implantation), etching, and deposition of various materials. Wafers are thus of key importance in the fabrication of semiconductor devices.

Wafers are made in various sizes ranging from 1 inch (25.4 mm) to 11.8 inches (300 mm), and thicknesses of the order of 0.1 to 0.5 mm. Generally, they are cut from a boule, i.e. a cylindrical rod, or from a multi crystalline block of semiconductor material, using a saw.

After cleaning the wafers, they are stacked together with a thin layer of water between each wafer. The wafers will be kept together due to the surface tension of the water. This makes it difficult to separate the wafers for further processing.

Removing the wafers from the stack has typically been done manually because the wafer material is brittle. Rough handling can easily result in breakage, or chipping of the edges, which would render the wafer useless for further manufacture.

To prevent such damage, vacuum “wands” are commonly employed as a means for manually lifting individual wafers from the stack. A wand typically consists of a stem with an internal channel for vacuum, a broad tip, and a vacuum actuator switch for connecting the stem to a vacuum source. An operator picks up a wafer by placing the broad tip of the wand in the centre of the planar surface of the wafer, thereby allowing the vacuum to cause the wafer to adhere to the wand.

Manually separating wafers has a number of drawbacks. The wafers in a stack have a tendency to stick to one another, primarily due to surface tension effects. A wand alone cannot overcome these effects, requiring the operator to slide the wafers apart by pushing against their edges. This handling can damage the wafers. Furthermore, the labour required is a significant processing cost and takes considerable time.

Attempts to automate the separating process have been tried but not widely adopted.

U.S. Pat. No. 5,213,451 describes the use of a dam and jets of fluid, such as water or oil, to separate wafers in a stack. The jets pushes the outermost wafer up and over the dam while the wafers beneath are restrained in the stack by the dam. A feed unit gradually lifts the wafer stack, causing each wafer to eventually be pushed over the dam by the fluid jets. While this method is faster than manually separating the wafers, it still exposes them to potential damage. The fluid jets cause the outermost wafer to slide against the adjacent wafer and drive the thin edges of the other wafers against the dam, either action of which can cause wafer breakage.

US-2001/0046435 addresses the problems described above. It describes a solution for individually separating the wafers by directing multiple jets of fluid between an outermost wafer in the stack and an adjacent wafer. The jets have sufficient pressure and are sufficiently spaced apart around the wafer stack to cause the outermost wafer to separate longitudinally from the adjacent wafer without lateral movement there between. The object is to separate the wafers in a stack without causing sliding contact between the wafers. Another objective is to separate the wafers without striking the wafer edges with a force sufficient to damage them.

Although the solutions presented above show automated methods with reduced risk for damaging wafers in the separation process, they still expose wafers for potential damage.

The present invention describes a new method for separating wafers with minimal risk for exposing them for damage. This is done by using a microwave stove for drying of wafers prior to separation.

Microwaves are a form of electromagnetic energy, where electromagnetic waves are in the frequency band 300 MHz to 300 GHz. Polar molecules and free ions in receptive materials respond to these fields by creating a molecular friction, which results in heat generated throughout the mass of the material. The interest for utilization of microwave energy for heating, sintering of ceramics and powdered metals, drying, binder removal, glass melting and plasma generation, is steadily increasing in the industry.

Microwave drying may play an increasingly important role in attempts to achieve shorter delivery times and reduce warehouse capacities.

Use of microwaves is gentle and time saving. In conventional drying, energy is applied to the surface of the material by radiation and convection, and must penetrate the inside in order to achieve uniform heating of the material. The thermal conductivity and heat resistance of the material mainly determines the heating process. Sensitive materials often will not allow high temperatures. If the material has poor thermal conductivity, an extension of the process is unavoidable. Conventional heating technologies, therefore, are subject to strict limitations in the manufacture of many products.

Microwave heating is very fast and easy to regulate. As soon as the microwave source is switched on, the waves immediately penetrate the body to be heated, and the conversion of energy begins. When the source is switched off, the heating process stops immediately. Long heating and cooling phases are not required.

Use of microwave energy for drying a stack of wafers according to the present invention has major potential and real advantages over conventional heating. The inventive method is space- and labour efficient. It demands less energy than known methods, and it is easy to control the energy supply, i.e. instantaneous control of energy supply with short heating up/cooling down periods.

### SUMMARY OF THE INVENTION

An object of the present invention is to provide a method for separating stacked wafers with minimal risk of breaking the wafers.

In order to arrive to the invention, the applicant has investigated two different methods involving drying the stack of wafers.

The first method investigated the use of a vacuum chamber where the evaporation is assisted by heating with internal heating means. The results showed that during heating in a vacuum chamber, the temperature in the wet wafers stabilizes at the boiling point at the given pressure. Using a heating element in bottom of the stack of wafers, gives a large gradient in the stack and it takes a long time to transfer the heat through the stack.

The second method investigated drying of wafers in a microwave stove, where microwave heating was investigated as a possible method for heating of the wafer stack.

The results of the two investigated methods and the dielectric constant of silicon (Si) and water has shown that the second method is the preferred one. The second method is both gentle and efficient for separating stacked wafers.

Consequently the invention claimed is a method for individually separating wafers from a stack of wafers kept together by the surface tension of a fluid, where the method comprises placing the stack of wafers in a microwave cabinet, and exposing the wafers for microwaves with an intensity and time period causing the water between the wafers to evaporate thereby releasing the force keeping the wafers together.

After exposing the stack of wafers to micro waves with an energy and time period sufficiently long for the water to vaporise, the wafers can easily be separated from each other either manually or automatically, e.g. by using a robot.

The invention is defined in the appended set of claims.

### DETAILED DESCRIPTION OF THE INVENTION

The inventive method for individually separating wafers from a stack of wafers kept together by the surface tension of a fluid will now be described in further detail.

The wafers are subjected to a drying process involving micro waves. The process comprises placing the stack of wafers in a microwave cabinet, and exposing the wafers for microwaves with an intensity and time period causing the fluid, preferably water between the wafers to evaporate.

The cabinet can be a standard cabinet used in microwave ovens for blocking electromagnetic waves outside of the cabinet in order to ensure radiation safety. The cabinet may either be closed or partly closed.

In a preferred embodiment, the cabinet further comprises temperature control means in addition to standard microwave oven means.

If the cabinet is closed, the cabinet can comprise vacuum pump means for applying vacuum in order to speed up the drying process. Other techniques may also be used, for instance hot air. Means for removing moisture produced in the process is preferably included. This is especially important if a closed cabinet is used.

The size of the cabinet will depend on the scale of the batch process, i.e. number of wafers to be treated at one time.

The appended FIGURE shows a schematic view of a batch process for drying stacked wafers.

For batch processing, the system comprises a conveyor belt. The conveyor belt will move the stack of wafers through the micro wave oven with a speed that is adjusted to the size and number of wafers to be treated, i.e. exposing the wafers for an energy and time period sufficiently long for the water to vaporise.

Microwaves can be combined with hot air and/or other techniques for speeding up the drying process.

In the following, a preferred method for separating wafers from a stack of wafers is described.

One or more stacks of wafers are placed in baskets made of microwave transparent material, i.e. material that does not pick up the electromagnetic field, and is resistant to high temperatures.

The baskets are placed on a conveyor belt that will load the wafers into the microwave cabinet. The conveyor belt may continuously move the stack of wafers through the micro waves, or stop for some time and then continue the transportation. This can be an automated process based on the weight of the stacks of wafers exposed to the micro waves.

The stack of wafers can contain just a few, or several hundred wafers. The stacks may be in a horizontal or vertical position, and the micro wave cabinet can hold one or several stacks at the same time.

The heat required to dry the wafers are the energy of evaporation, i.e. the energy required to heat the wafers to the process temperature plus heat losses to the surroundings.

To determine the power required for microwave drying, the rule of thumb is that a microwave output of 1 kW is required to evaporate 1 kg of water per hour. This rule applies as long as initially there is sufficient moisture.

In has been shown that an assembly of 300 silicon slices, containing a total of 63 grams of water will need less than 15 minutes to evaporate with a supplied intensity of 1 kW. This illustrates that a microwave working at 1 kW output has the capacity of drying more than 20 kg of wet silicon wafers within 1 hour, i.e. approximately 500 kg/day in continuous operation.

In order to achieve an efficient batch process that can keep up with the production speed of wafers several parameters must be combined. Power, time and water volume must be combined in order to achieve a gentle and fast drying process. The time is given by the speed of the conveyor belt and the length of the tunnel formed by the cabinet. The power can be in the range from 0.1 kW to 100 kW.

The invention has been described by a preferred example with reference to the FIGURE. However, a skilled person in the art will realize that several variations and alternatives exist within the scope of the invention, as set forth in the appended set of claims.

The main principle of the invention is the described method involving use of micro waves for drying a stack of wafers. After the drying process the stack of wafers can be separated either manually or automatically.

In the case of an automatic process, a robot can be used for the purpose of separation, either inside or outside of the cabinet where the drying process is taking place.

If an automatic separation of the wafers is to take place inside the drying cabinet there are different preferred methods for doing this depending on the size of the cabinet.

In case of a small cabinet with room for just one stack of wafers at a time, the drying process can be stopped followed by letting a robot inside the cabinet perform the separation.

In one embodiment directional controlled antennas for emitting micro waves can be use such that one end of the stack of wafers is irradiated and consequently dried before the other. If this method is used wafers can be removed from the dried part of the stack, while the other part is being dried by means of the directionally controlled micro waves. This technique will speed up the drying and separation process.

In case of a larger cabinet for drying more than one stack of wafers, the wafers entering the cabinet can be irradiated with micro waves, while a stack being moved to the other end of the cabinet can be handled by robot means separating wafers from the stack of wafers.

If on the other hand the separation is to take place outside of the drying cabinet, a robot can pick up the stack of wafers after being dried and bring it over to the location where separation is to take place.

The present invention is not restricted to silicon wafers, but can be use on all kinds of wafers. The method can further be used on all kinds of disks held together by surface tension, i.e. a fluid.

1-10. (canceled)

11. A method for individually separating wafers from a stack of wafers kept together by the surface tension of a fluid, said method comprising the steps of:
placing the stack of wafers in a microwave cabinet; and
exposing the wafers to microwaves with an intensity and time period causing the fluid between the wafers to evaporate.

12. The method according to claim 11, wherein the fluid is water.

13. The method according to claim 11, wherein the wafers are silicon wafers.

14. The method according to claim 11, wherein the microwave cabinet has atmospheric pressure.

15. The method according to claim 11, wherein the microwave cabinet is a vacuum chamber.

16. The method according to claim 11, further comprising the step of adjusting the intensity of the microwaves and the exposure time such that the amount of water between the wafers has evaporated.

17. The method according to claim 11, further comprising the step of directionally controlling the microwaves such that one part of a stack will dry before the other, thus enabling separation of wafers from the dry part while the wet part is drying.

18. A System for individually separating wafers from a stack of wafers kept together by the surface tension of a fluid, comprising:
a microwave cabinet with means for exposing the wafers to microwaves, causing the fluid between the wafers to evaporate; and
robot means for separating wafers.

19. The system according to claim 18, wherein the robot means is located inside the microwave cabinet.

20. The system according to claim 18, wherein the robot means is located outside the microwave cabinet.
